(19) United States
(12) Patent Application Publication
(10) Pub. No.: US 2025/0285946 A1
(43) Pub. Date: Sep. 11, 2025

(54) SEMICONDUCTOR DEVICE AND POWER CONVERSION DEVICE

(71) Applicant: Mitsubishi Electric Corporation, Tokyo (JP)

(72) Inventors: Hiroshi IWANAGA, Tokyo (JP); Tatsunori YANAGIMOTO, Tokyo (JP); Yoshihisa UCHIDA, Tokyo (JP); Hiroshi UEDA, Tokyo (JP)

(73) Assignee: Mitsubishi Electric Corporation, Tokyo (JP)

(21) Appl. No.: 19/031,292

(22) Filed: Jan. 17, 2025

(30) Foreign Application Priority Data
Mar. 6, 2024 (JP) 2024-033678

(51) Int. Cl. H01L 23/495; H01L 23/00; H01L 23/538; H01L 25/07

(52) U.S. Cl. CPC H01L 23/49548; H01L 24/48; H01L 23/538; H01L 25/072; H01L 2224/48108; H01L 2224/48137; H01L 2224/48175

(57) ABSTRACT

There is provided a semiconductor device in which the occurrence of a short-circuit failure is suppressed. A semiconductor device includes: a substrate; a semiconductor element; a terminal; and a metal wire. The semiconductor element is disposed on the substrate. The terminal is disposed at a position farther than the semiconductor element when viewed from the substrate. The metal wire connects the semiconductor element and the terminal. A notch portion is provided in the terminal. A part of the metal wire is inserted into the notch portion.

### CROSS REFERENCE TO RELATED APPLICATIONS

This nonprovisional application is based on Japanese Patent Application No. 2024-033678 filed on Mar. 6, 2024 with the Japan Patent Office, the entire contents of which are hereby incorporated by reference.

### BACKGROUND OF THE INVENTION

### Field of the Invention

The present disclosure relates to a semiconductor device and a power conversion device.

### Description of the Background Art

A wire bonding method using a metal wire has been conventionally known as a method for forming internal wiring in a semiconductor device (refer to, for example, Japanese Utility Model Laying-Open No. 1-163345 (full text)). In Japanese Utility Model Laying-Open No. 1-163345, a metal wire is formed along a direction in which a terminal extends.

### SUMMARY OF THE INVENTION

However, in a semiconductor device of transfer mold type, a metal wire may be deformed by a mold resin when the mold resin is injected as a sealing resin. The deformation of the metal wire may consequently cause a short-circuit failure.

The present disclosure has been made to solve the above-described problem, and an object of the present disclosure is to provide a semiconductor device in which the occurrence of a short-circuit failure is suppressed.

A semiconductor device according to the present disclosure includes: a substrate; a semiconductor element; a terminal; and a metal wire. The semiconductor element is disposed on the substrate. The terminal is disposed at a position farther than the semiconductor element when viewed from the substrate. The metal wire connects the semiconductor element and the terminal. A notch portion is provided in the terminal. A part of the metal wire is inserted into the notch portion.

A power conversion device according to the present disclosure includes: a main conversion circuit; and a control circuit. The main conversion circuit has the above-described semiconductor device, and converts input power and outputs the converted input power. The control circuit outputs a control signal for controlling the main conversion circuit to the main conversion circuit.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a side view of a semiconductor device according to a first embodiment.

FIG. 2 is a plan view of the semiconductor device according to the first embodiment.

FIG. 3 is a partially enlarged side view of a region III shown in FIG. 1.

FIG. 4 is a plan view of a signal terminal according to the first embodiment.

FIG. 5 is a side view of a semiconductor device according to a second embodiment.

FIG. 6 is a plan view of the semiconductor device according to the second embodiment.

FIG. 7 is a side view of a semiconductor device according to a third embodiment.

FIG. 8 is a plan view of the semiconductor device according to the third embodiment.

FIG. 9 is a plan view of a signal terminal according to the third embodiment.

FIG. 10 is a side view of a semiconductor device according to a fourth embodiment.

FIG. 11 is a partially enlarged side view of a region XI shown in FIG. 10.

FIG. 12 is a plan view of a signal terminal according to a fifth embodiment.

FIG. 13 is a plan view of a signal terminal according to a sixth embodiment.

FIG. 14 is a block diagram showing a configuration of a power conversion system to which a power conversion device according to a seventh embodiment is applied.

### DESCRIPTION OF THE PREFERRED EMBODIMENTS

Hereinafter, embodiments of the present disclosure will be described. Unless otherwise mentioned, the same or corresponding portions in the following drawings are denoted by the same reference numerals, and description thereof will not be repeated.

### First Embodiment

### <Configuration of Semiconductor Device>

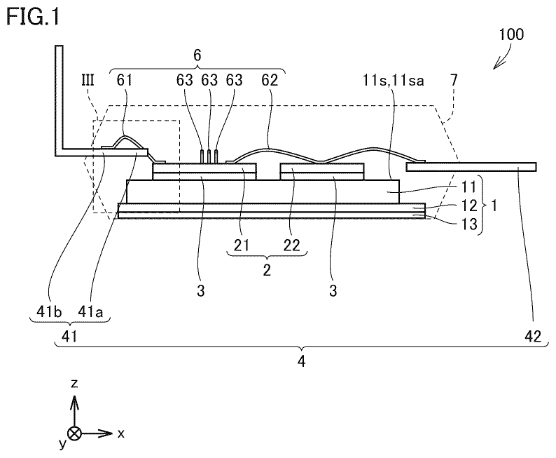

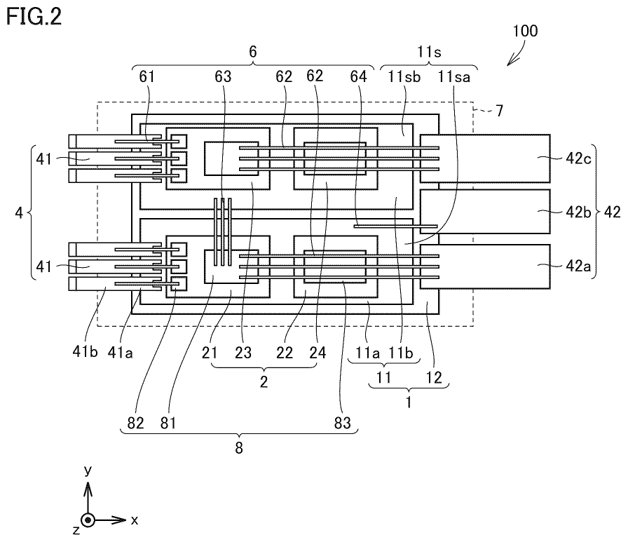

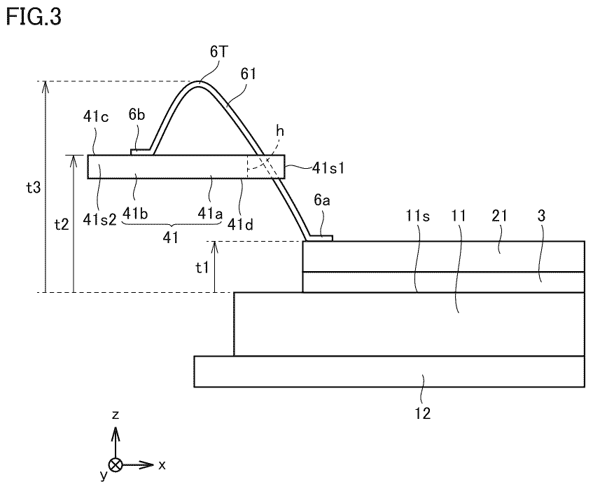

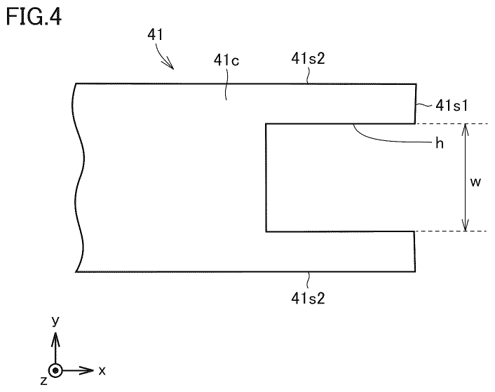

FIG. 1 is a side view of a semiconductor device 100 according to a first embodiment. FIG. 2 is a plan view of semiconductor device 100 according to the first embodiment. FIG. 3 is a partially enlarged side view of a region III shown in FIG. 1. FIG. 4 is a plan view of a signal terminal 41 according to the first embodiment.

Semiconductor device 100 shown in FIGS. 1 to 4 is, for example, power semiconductor device 100 and mainly includes a substrate 1, a semiconductor element 2, a joining portion 3, a terminal 4, a metal wire 6, and a sealing portion 7. In FIGS. 1 and 2, sealing portion 7 is indicated by a dotted line.

Substrate 1 has a heat spreader 11, an insulating sheet 12 and a metal foil 13. Heat spreader 11 is disposed on insulating sheet 12. Insulating sheet 12 is disposed on metal foil 13. Metal foil 13 is disposed on a surface of insulating sheet 12 located opposite to a surface on which heat spreader 11 is disposed.

A material of heat spreader 11 is, for example, copper (Cu). As shown in FIG. 2, heat spreader 11 includes a plurality of heat spreader portions 11a and 11b. The plurality of heat spreader portions 11a and 11b are disposed to be spaced apart from each other in the y direction.

As shown in FIG. 2, substrate 1 has a main surface 11s. Main surface 11s is a surface to which semiconductor element 2 is electrically connected. Heat spreader portion 11a has a surface 11sa. Heat spreader portion 11b has a surface 11sb. Surfaces 11sa and 11sb form main surface 11s of substrate 1.

As shown in FIGS. 1 and 2, a direction perpendicular to main surface 11s is defined as the z direction. The x direction and the y direction are directions perpendicular to the z direction. The y direction is a direction perpendicular to the x direction. That is, main surface 11s is a surface extending in the x direction and the y direction.

Insulating sheet 12 is connected to a surface of heat spreader 11 located opposite to surface 11sa and surface 11sb. Insulating sheet 12 may be, for example, an insulating sheet containing inorganic powder or glass fiber. Metal foil 13 and heat spreader 11 are electrically insulated by insulating sheet 12.

A material of metal foil 13 may be a metal having high thermal conductivity. The material of metal foil 13 may be, for example, any material selected from the group consisting of aluminum, copper, iron, and nickel, or may be an alloy containing at least any material selected from the group consisting of aluminum, copper, iron, and nickel.

As shown in FIGS. 1 and 2, in a plan view of main surface 11s, heat spreader 11 may be smaller than each of insulating sheet 12 and metal foil 13 in the x direction and the y direction.

Substrate 1 having a three-layer structure constituted by heat spreader 11, insulating sheet 12 and metal foil 13 may be used as substrate 1, or an insulating substrate may be used as substrate 1. The insulating substrate may be constituted by a base plate, an insulating layer and a circuit pattern. The insulating layer may be disposed on the base plate, and the circuit pattern may be disposed on the insulating layer. Each of the base plate and the circuit pattern is made of metal such as copper, for example. The insulating layer ensures electrical insulation from the outside of semiconductor device 100. A material of the insulating layer may be, for example, inorganic ceramic, or may be a material having ceramic powder dispersed in a thermosetting resin such as an epoxy resin.

Semiconductor element 2 includes a plurality of semiconductor element portions 21, 22, 23, and 24. As shown in FIG. 1, semiconductor element 2 is connected to main surface 11s of substrate 1 with joining portion 3 interposed therebetween. Specifically, each of semiconductor element portions 21 and 22 is connected to surface 11sa with joining portion 3 interposed therebetween. Each of semiconductor element portions 23 and 24 is connected to surface 11sb with joining portion 3 (not shown) interposed therebetween.

A material of joining portion 3 may be, for example, solder, or may be an electrically conductive adhesive, or may be a joining material containing silver (Ag) particles or copper (Cu) particles having sinterability. By using the joining material having sinterability to join semiconductor element 2 and substrate 1, the heat dissipation properties and lifespan of joining portion 3 are improved, as compared with when solder is used.

Semiconductor element 2 is so-called power semiconductor element 2 that controls electric power. A material of semiconductor element 2 may be silicon (Si), or may be silicon carbide (SiC), gallium nitride (GaN), gallium oxide (Ga203), or diamond as a wide bandgap semiconductor material. When such a so-called wide bandgap semiconductor material having a wider bandgap than that of silicon is used as the material of semiconductor element 2, semiconductor device 100 with high efficiency and compatible with high temperatures can be obtained.

Semiconductor element 2 may be of any kind. For example, an insulated gate bipolar transistor (IGBT), a free wheel diode (FWD), or a metal oxide semiconductor field effect transistor (MOSFET) can be used.

As shown in FIG. 2, semiconductor element portions 21 and 22 are disposed to be spaced apart from each other in the x direction. Semiconductor element portions 23 and 24 are disposed to be spaced apart from each other in the x direction.

As shown in FIG. 2, each of semiconductor element portions 21 and 23 has a main electrode 81 and three signal electrodes 82. Main electrode 81 and three signal electrodes 82 are provided on a surface (upper surface) of each of semiconductor element portions 21 and 23. Each of semiconductor element portions 22 and 24 has a main electrode 83. Main electrode 83 is provided on a surface (upper surface) of each of semiconductor element portions 22 and 24. Main electrode 81 is disposed to be spaced apart from each of three signal electrodes 82 in the x direction. Three signal electrodes 82 may be disposed to be spaced apart from each other at equal intervals in the y direction.

Terminal 4 has a main terminal 42 and a plurality of signal terminals 41. As shown in FIG. 2, main terminal 42 includes a plurality of main terminal portions 42a, 42b and 42c. Metal wire 6 connects semiconductor element 2 and terminal 4. Metal wire 6 includes a plurality of metal wire portions 61, 62, 63, and 64. In semiconductor device 100 according to the first embodiment, six metal wire portions 61, six metal wire portions 62, three metal wire portions 63, and one metal wire portion 64 are provided.

Each of three metal wire portions 62 connects main terminal portion 42a, main electrode 83 of semiconductor element portion 22, and main electrode 81 of semiconductor element portion 21 by a wire bonding method. Each of three metal wire portions 62 connects main terminal portion 42c, main electrode 83 of semiconductor element portion 24, and main electrode 81 of semiconductor element portion 23 by a wire bonding method. In this way, main terminal 42 through which a main current flows is electrically connected to main electrodes 81 and 83 that input and output main power.

Each of six metal wire portions 61 connects each of six signal terminals 41 and each of six signal electrodes 82 of semiconductor element portions 21 and 23 by a wire bonding method. In this way, signal terminal 41 through which a control signal flows is electrically connected to signal electrode 82 that inputs and outputs a control signal and a sense signal.

As shown in FIG. 2, each of three metal wire portions 63 may connect main electrode 81 of semiconductor element portion 21 and surface 11sb of heat spreader portion 11b by a wire bonding method. Metal wire portion 64 may connect main terminal portion 42b and surface 11sa of heat spreader portion 11a by a wire bonding method.

A material of metal wire 6 may be any metal, and may be, for example, aluminum (Al) or copper (Cu). A diameter of metal wire 6 may be, for example, equal to or more than 80 μm and equal to or less than 600 μm. Particularly, a diameter of metal wire portion 62 through which the main current flows may be 400 μm. On the other hand, a diameter of metal wire portion 61 through which the control signal and the like flow may be 200 μm.

A material of terminal 4 is, for example, copper (Cu). The material of terminal 4 may be any material having heat dissipation properties in addition to electrically conductive properties. The material of terminal 4 may be, for example, an alloy containing copper or aluminum, or may be a composite material obtained by stacking these metals.

A part of each of the plurality of main terminal portions 42a, 42b and 42c and the plurality of signal terminals 41 extends in the x direction from semiconductor element 2 to the outside of sealing portion 7. Signal terminal 41 extends along a direction opposite to a direction in which main terminal 42 extends.

Sealing portion 7 covers substrate 1, semiconductor element 2, joining portion 3, a part of main terminal 42, a part of signal terminal 41, and metal wire 6. As shown in FIG. 1, a surface of metal foil 13 located opposite to a surface connected to insulating sheet 12 may be exposed from sealing portion 7. When semiconductor device 100 is incorporated into a power conversion device or the like, metal foil 13 may be connected to a heat dissipation fin in the portion of metal foil 13 exposed from sealing portion 7. In order to electrically insulate metal foil 13 from the outside, sealing portion 7 may cover the whole of metal foil 13.

A part of terminal 4 extends from a surface of sealing portion 7 to the outside such that terminal 4 can be connected to an external device outside sealing portion 7. The portion of terminal 4 extending to the outside of sealing portion 7 may be bent by, for example, forming. A conductor (not shown) such as a wire or a terminal for electrical connection to a circuit board or another semiconductor device may be connected to the above-described portion of terminal 4. Any method can be used as a method for connecting the conductor and the above-described portion, and the conductor and the above-described portion may be fixed by, for example, a fixing member such as a screw.

A material of sealing portion 7 may be a resin having insulating properties. The resin having insulating properties may be, for example, an epoxy resin. Sealing portion 7 may be formed by transfer molding.

As described above, as metal wire 6, metal wire portion 61 connects semiconductor element 2 and terminal 4. When signal terminal 41 is disposed as terminal 4 at the same level as semiconductor element 2 in the z direction, a position in the z direction at which metal wire portion 61 is connected to signal terminal 41 is the same as a position at which metal wire portion 61 is connected to semiconductor element 2.

The diameter of metal wire portion 61 is smaller than the diameter of metal wire portion 62. Therefore, when a resin is injected during formation of sealing portion 7, metal wire portion 61 may be crushed along the −z direction and deformed due to an injection pressure of the resin. When deformed metal wire portion 61 comes into contact with a member (e.g., heat spreader 11) having a potential different from a potential of metal wire portion 61, a short-circuit failure occurs in semiconductor device 100.

Furthermore, when the plurality of metal wire portions 61 are disposed to be adjacent to each other, metal wire portions 61 adjacent to each other may come into contact with each other during manufacturing of semiconductor device 100, due to vibrations generated during transport of semiconductor device 100 or the injection pressure of the resin during injection of the resin. As a result, a short-circuit failure occurs in semiconductor device 100.

Semiconductor device 100 according to the first embodiment is characterized in that a notch portion h is provided in terminal 4 as shown in FIG. 4. By disposing terminal 4 such that a part of metal wire 6 is inserted into notch portion h, deformation and movement of metal wire 6 are limited by notch portion h. As a result, contact between metal wire 6 and the other members, and contact between metal wires 6 adjacent to each other are suppressed. In this way, the occurrence of a short-circuit failure in semiconductor device 100 is suppressed.

In addition, signal terminal 41 is disposed at a position farther than semiconductor element 2 when viewed from substrate 1. Therefore, metal wire 6 on the connection portion 6a side connected to semiconductor element 2 with respect to a center of metal wire 6 in the x direction is held, and thus, deformation of metal wire 6 is further suppressed.

As shown in FIGS. 3 and 4, signal terminal 41 has an upper surface 41c, a lower surface 41d, a tip end surface 41s1, and a pair of side surfaces 41s2. Upper surface 41c and lower surface 41d are surfaces substantially perpendicular to the z direction. Upper surface 41c and lower surface 41d face each other in the z direction. Notch portion h passes through signal terminal 41 to extend from upper surface 41c to lower surface 41d.

As shown in FIG. 4, signal terminal 41 extends in the x direction within sealing portion 7. Each of tip end surface 41s1 and the pair of side surfaces 41s2 is continuous to upper surface 41c and lower surface 41d. Tip end surface 41s1 may be a surface substantially perpendicular to the x direction. The pair of side surfaces 41s2 face each other in the y direction. The pair of side surfaces 41s2 may be surfaces substantially perpendicular to the y direction. Notch portion h may be opened to tip end surface 41s1. Notch portion h may be disposed at a position where notch portion h is sandwiched between the pair of side surfaces 41s2 in the y direction, or may be provided at a center of signal terminal 41 in the width direction (in the first embodiment, the y direction).

A distance t2 from main surface 11s of substrate 1 to upper surface 41c of signal terminal 41 is longer than a distance t1 from main surface 11s of substrate 1 to a surface of semiconductor element portion 21. Thus, a part of metal wire portion 61 is inserted into notch portion h.

From a different point of view, as shown in FIG. 3, metal wire portion 61 includes vertex portion 6T and connection portions 6a and 6b. Vertex portion 6T is a portion of metal wire portion 61 disposed at a position farthest from semiconductor element 2 in the z direction. Connection portion 6a is a portion of metal wire portion 61 that is in contact with signal electrode 82. Connection portion 6b is a portion of metal wire portion 61 that is in contact with signal terminal 41.

As described above, signal terminal 41 is disposed at the position farther than semiconductor element 2 when viewed from substrate 1. Therefore, connection portion 6b is disposed at a position farther than connection portion 6a in the z direction when viewed from semiconductor element portion 21. In addition, metal wire portion 61 is formed to be curved. Therefore, vertex portion 6T is disposed at a position farther than connection portion 6b in the z direction when viewed from semiconductor element portion 21. From a different point of view, a distance t3 from substrate 1 to vertex portion 6T is longer than distance t1 from substrate 1 to connection portion 6a, and is longer than distance t2 from substrate 1 to connection portion 6b. Thus, a tip end of signal terminal 41 can suppress deformation of metal wire portion 61 in the −z direction, and suppress contact with the other members in metal wire portion 61.

A part of metal wire portion 61 is surrounded by notch portion h in a plan view of main surface 11s. Thus, contact between metal wires 6 adjacent to each other can be suppressed. Even if metal wire 6 comes into contact with an inner wall of terminal 4 that forms notch portion h, the characteristics of semiconductor device 100 are not affected because metal wire 6 and terminal 4 have an equal potential.

When a width w of notch portion h in the y direction is large, an amount of movement of metal wire portion 61 is large. When width w of notch portion h in the y direction is small, it is difficult to insert metal wire portion 61 into notch portion h. Therefore, width w of notch portion h in the y direction may be equal to or more than 1.5 times and equal to or less than 2 times the diameter of metal wire portion 61.

Furthermore, as shown in FIG. 3, a part of a region of metal wire portion 61 from connection portion 6a to vertex portion 6T is inserted into notch portion h (see the dotted line in FIG. 3). From a different point of view, notch portion h is disposed between vertex portion 6T and connection portion 6a in the x direction. Particularly, notch portion h may be disposed on the connection portion 6a side with respect to a center of metal wire portion 61 in the x direction. Thus, since notch portion h holds metal wire portion 61 on the connection portion 6a side, deformation of metal wire portion 61 is further suppressed. As a result, the occurrence of a short-circuit failure in semiconductor device 100 is suppressed.

Notch portion h may only be disposed between vertex portion 6T and connection portion 6a in the z direction. Notch portion h may be disposed at a center between vertex portion 6T and connection portion 6a in the z direction. Notch portion h may be disposed on the vertex portion 6T side when viewed from the center between vertex portion 6T and connection portion 6a. Notch portion h may be disposed on the connection portion 6a side when viewed from the center between vertex portion 6T and connection portion 6a.

When signal terminal 41 is disposed so as not to overlap with substrate 1, metal wire portion 61 becomes longer. As a result, semiconductor device 100 increases in size in the x direction. In addition, when metal wire portion 61 becomes longer, deformation of metal wire portion 61 may become larger during manufacturing of semiconductor device 100, due to vibrations generated during transport of semiconductor device 100 or the injection pressure of the resin during injection of the resin.

Therefore, as shown in FIGS. 1 to 3, a part of signal terminal 41 may be disposed at a position where the part of signal terminal 41 overhangs substrate 1. Specifically, a part of signal terminal 41 may overlap with substrate 1 in a plan view of main surface 11s. Thus, since signal terminal 41 is disposed such that a part thereof overlaps with substrate 1, the length of metal wire portion 61 can be reduced even when substrate 1 is increased in size. As a result, an increase in size of semiconductor device 100 in the x direction can be suppressed.

Signal terminal 41 includes a tip end region 41a and an external region 41b. Tip end region 41a is a region where signal terminal 41 overlaps with substrate 1 in a plan view of main surface 11s. External region 41b is a region of signal terminal 41 other than tip end region 41a, and is a region where signal terminal 41 does not overlap with substrate 1 in a plan view of main surface 11s.

Notch portion h is provided in tip end region 41a of signal terminal 41. Connection portion 6b is connected to external region 41b of signal terminal 41 in the x direction. That is, connection portion 6b is disposed at a position that does not overlap with substrate 1 in a plan view of main surface 11s.

Thus, an increase in size of semiconductor device 100 in the x direction can be suppressed. With an increase in size of substrate 1, heat spreader 11 may be increased in size. As a result, the heat dissipation properties of semiconductor device 100 can be improved. In addition, by reducing the length of metal wire portion 61, deformation of metal wire portion 61 during manufacturing of semiconductor device 100 due to vibrations generated during transport of semiconductor device 100 or the injection pressure of the resin during injection of the resin can be suppressed.

The example in which notch portion h is provided in signal terminal 41 has been described. However, notch portion h may be provided in main terminal 42, or the above-described configuration may be applied to main terminal 42 and metal wire portions 62 and 64.

### Functions and Effects

Semiconductor device 100 according to the present disclosure includes substrate 1, semiconductor element 2, terminal 4, and metal wire 6. Semiconductor element 2 is disposed on substrate 1. Terminal 4 is disposed at the position farther than semiconductor element 2 when viewed from substrate 1. Metal wire 6 connects semiconductor element 2 and terminal 4. Notch portion h is provided in terminal 4. A part of metal wire 6 is inserted into notch portion h.

With such a configuration, contact between metal wire 6 and the other members, and contact between metal wires 6 adjacent to each other are suppressed. As a result, the occurrence of a short-circuit failure in semiconductor device 100 is suppressed.

According to semiconductor device 100 described above, terminal 4 includes tip end region 41a and external region 41b. Tip end region 41a overlaps with substrate 1 in a plan view of substrate 1. External region 41b is a region other than tip end region 41a. Metal wire 6 is connected to external region 41b.

With such a configuration, an increase in size of semiconductor device 100 in the direction in which terminal 4 extends can be suppressed. In addition, by reducing the length of metal wire 6, deformation of metal wire 6 during manufacturing of semiconductor device 100 due to vibrations generated during transport of semiconductor device 100 or the injection pressure of the resin during injection of the resin can be suppressed.

According to semiconductor device 100 described above, notch portion h is provided at the center of terminal 4 in the width direction.

With such a configuration, contact between metal wire 6 and the other members, and contact between metal wires 6 adjacent to each other are suppressed. As a result, the occurrence of a short-circuit failure in semiconductor device 100 is suppressed.

### Second Embodiment

### <Configuration of Semiconductor Device>

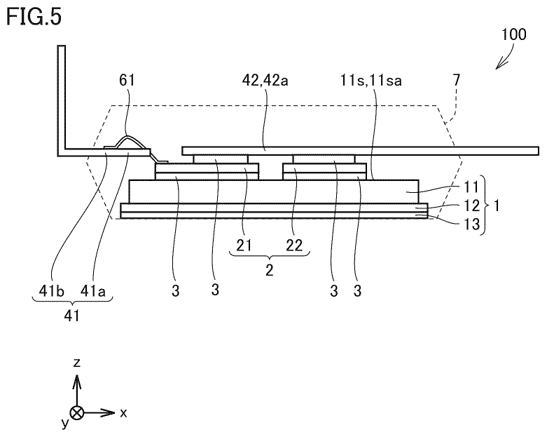

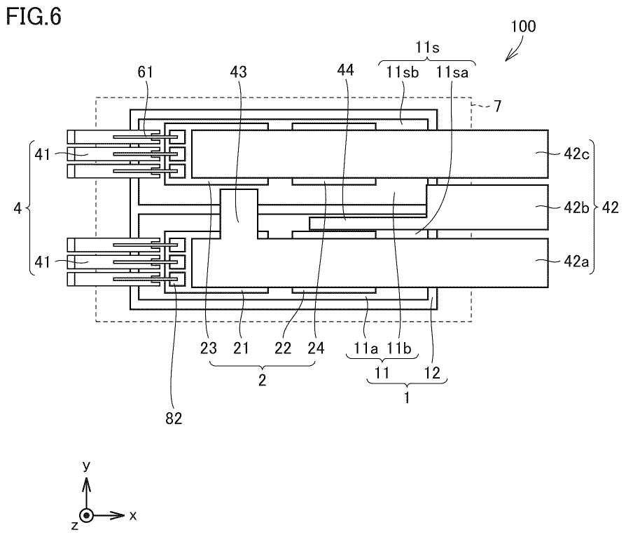

FIG. 5 is a side view of semiconductor device 100 according to a second embodiment. FIG. 5 corresponds to FIG. 1. FIG. 6 is a plan view of semiconductor device 100 according to the second embodiment. FIG. 6 corresponds to FIG. 2. Semiconductor device 100 shown in FIGS. 5 and 6 basically has the same configuration as that of semiconductor device 100 shown in FIGS. 1 to 4 and can achieve the same effect as that of semiconductor device 100 shown in FIGS. 1 to 4. However, semiconductor device 100 shown in FIGS. 5 and 6 is different from semiconductor device 100 shown in FIGS. 1 to 4 in that main electrodes 81 and 83 (see FIG. 2) are connected to main terminal 42 with joining portions 3 interposed therebetween.

As shown in FIG. 6, main terminal portion 42a may extend to a position that overlaps with main electrode 81 of semiconductor element portion 21 in the x direction. Main terminal portion 42b may have a protruding portion 44 extending in the x direction. Main terminal portion 42c may extend to a position that overlaps with main electrode 81 of semiconductor element portion 23 in the x direction.

As shown in FIG. 5, main terminal portion 42a is connected to main electrode 81 of semiconductor element portion 21 with joining portion 3 interposed therebetween. Main terminal portion 42a is connected to main electrode 83 of semiconductor element portion 22 with joining portion 3 interposed therebetween. Main terminal portion 42a may have a protruding portion 43. Protruding portion 43 extends from main terminal portion 42a in the y direction to overlap with surface 11sb of heat spreader portion 11b. Protruding portion 43 is connected to surface 11sb of heat spreader portion 11b with joining portion 3 (not shown) interposed therebetween.

Protruding portion 44 is connected to surface 11sa of heat spreader portion 11a with joining portion 3 (not shown) interposed therebetween.

As shown in FIG. 6, main terminal portion 42c is connected to main electrode 81 of semiconductor element portion 23 with joining portion 3 (not shown) interposed therebetween. Main terminal portion 42c is connected to main electrode 83 of semiconductor element portion 24 with joining portion 3 (not shown) interposed therebetween.

By connecting main terminal 42 to main electrodes 81 and 83 with joining portions 3 (made of solder) interposed therebetween as described above, the heat cycle resistance and lifespan of semiconductor device 100 are improved, as compared with when main terminal 42 and main electrodes 81 and 83 are connected to each other with metal wire portions 62 interposed therebetween.

A material of joining portions 3 that connect main terminal 42 and main electrodes 81 and 83 may be, for example, solder, or may be an electrically conductive adhesive, or may be a joining material containing silver (Ag) particles or copper (Cu) particles having sinterability. By using the joining material having sinterability to join main terminal 42 and main electrodes 81 and 83, the heat dissipation properties and lifespan of joining portions 3 are improved, as compared with when solder is used.

### <Functions and Effects>

According to semiconductor device 100 described above, semiconductor element 2 has main electrode 81 and signal electrode 82. Terminal 4 has main terminal 42 and signal terminal 41. Main terminal 42 is connected to main electrode 81 with joining portion 3 interposed therebetween. Signal terminal 41 is connected to signal electrode 82 via metal wire 6.

With such a configuration, the heat cycle resistance and lifespan of semiconductor device 100 are improved.

### Third Embodiment

### <Configuration of Semiconductor Device>

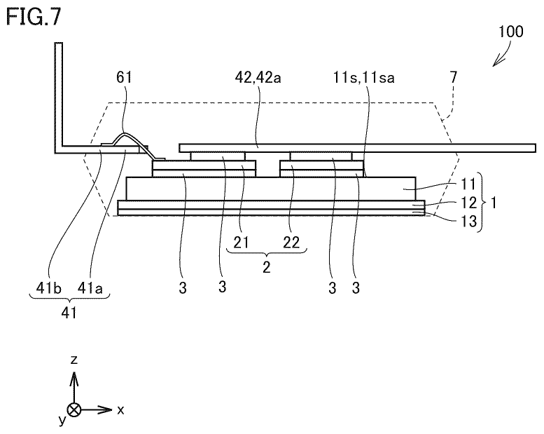

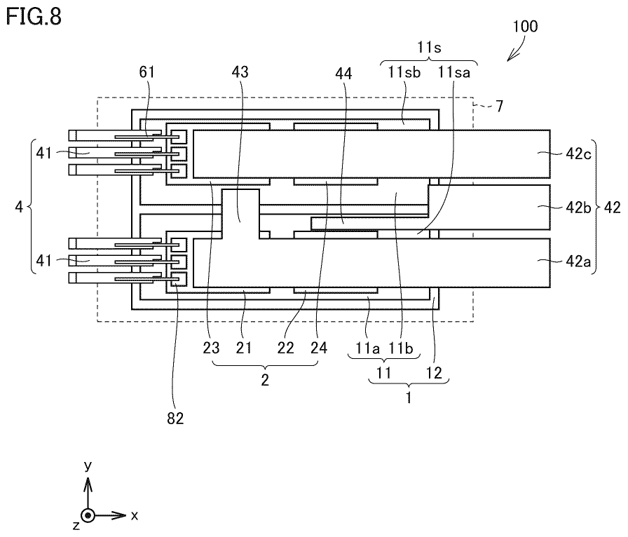

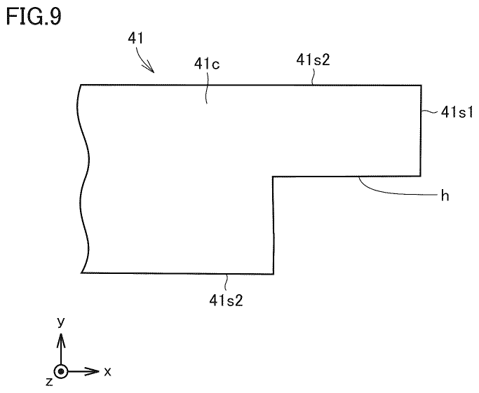

FIG. 7 is a side view of semiconductor device 100 according to a third embodiment. FIG. 7 corresponds to FIG. 5. FIG. 8 is a plan view of semiconductor device 100 according to the third embodiment. FIG. 8 corresponds to FIG. 6. FIG. 9 is a plan view of terminal 4 according to the third embodiment. FIG. 9 corresponds to FIG. 4. Semiconductor device 100 shown in FIGS. 7 to 9 basically has the same configuration as that of semiconductor device 100 shown in FIGS. 5 and 6 and can achieve the same effect as that of semiconductor device 100 shown in FIGS. 5 and 6. However, semiconductor device 100 shown in FIGS. 7 to 9 is different from semiconductor device 100 shown in FIGS. 5 and 6 in that notch portion h is provided at an end of terminal 4 in the width direction.

From a different point of view, notch portion h may be opened toward tip end surface 41s1 and one of the pair of side surfaces 41s2.

With such a configuration, the width of signal terminal 41 in the y direction can be reduced. As a result, semiconductor device 100 can be reduced in size in the y direction. In addition, the material of signal terminal 41 can be reduced.

### <Functions and Effects>

According to semiconductor device 100 described above, notch portion h is provided at the end of terminal 4 in the width direction.

With such a configuration, the width of signal terminal 41 in the y direction can be reduced. As a result, semiconductor device 100 can be reduced in size in the y direction. In addition, the material of signal terminal 41 can be reduced.

### Fourth Embodiment

### <Configuration of Semiconductor Device>

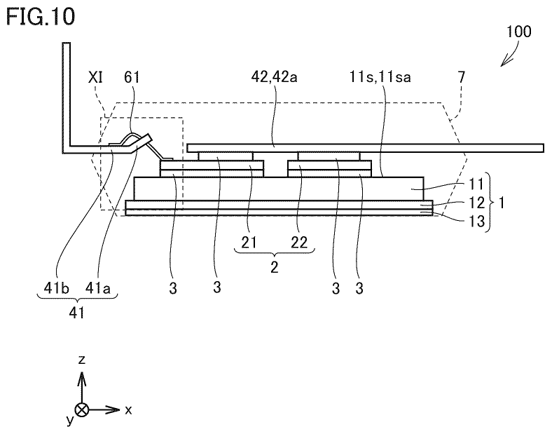

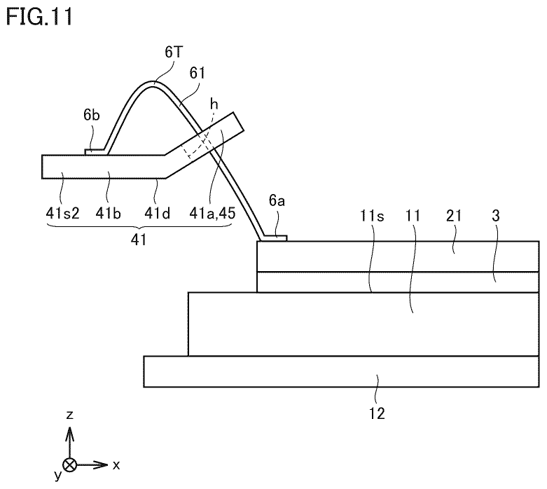

FIG. 10 is a side view of semiconductor device 100 according to a fourth embodiment. FIG. 10 corresponds to FIG. 5. FIG. 11 is a partially enlarged side view of a region XI shown in FIG. 10. FIG. 11 corresponds to FIG. 3. Semiconductor device 100 shown in FIGS. 10 and 11 basically has the same configuration as that of semiconductor device 100 shown in FIGS. 5 and 6 and can achieve the same effect as that of semiconductor device 100 shown in FIGS. 5 and 6. However, semiconductor device 100 shown in FIGS. 10 and 11 is different from semiconductor device 100 shown in FIGS. 5 and 6 in that a tip end of terminal 4 is inclined with respect to the z direction.

As terminal 4, signal terminal 41 has an inclined portion 45. Inclined portion 45 is disposed at tip end region 41a of signal terminal 41. Inclined portion 45 is inclined to be located between connection portion 6b and vertex portion 6T in the z direction, which is a direction perpendicular to main surface 11s of substrate 1.

By inclining the tip end of signal terminal 41 in the z direction as described above, the position of notch portion h in the z direction can be changed. As a result, deformation of metal wire 6 during manufacturing of semiconductor device 100 due to vibrations generated during transport of semiconductor device 100 or the injection pressure of the resin during injection of the resin can be suppressed.

### <Functions and Effects>

According to semiconductor device 100 described above, metal wire 6 has vertex portion 6T and connection portion 6b. Vertex portion 6T is farthest from semiconductor element 2. Connection portion 6b is in contact with terminal 4. Terminal 4 has inclined portion 45. Inclined portion 45 is located between connection portion 6b and vertex portion 6T in the direction perpendicular to main surface 11s of substrate 1.

With such a configuration, contact between metal wire 6 and the other members, and contact between metal wires 6 adjacent to each other are suppressed.

As a result, the occurrence of a short-circuit failure in semiconductor device 100 is suppressed.

### Fifth Embodiment

### <Configuration of Semiconductor Device>

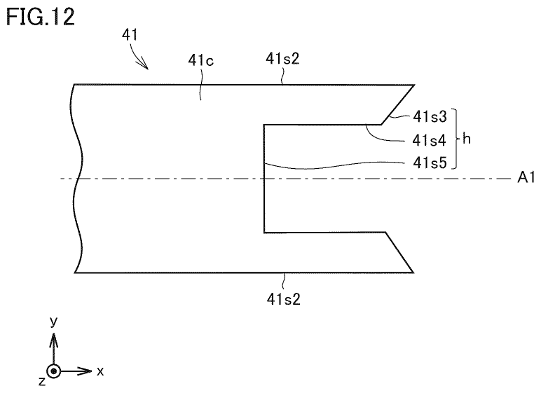

FIG. 12 is a plan view of signal terminal 41 according to a fifth embodiment. FIG. 12 corresponds to FIG. 4. Semiconductor device 100 shown in FIG. 12 basically has the same configuration as that of semiconductor device 100 shown in FIGS. 1 to 4 and can achieve the same effect as that of semiconductor device 100 shown in FIGS. 1 to 4. However, semiconductor device 100 shown in FIG. 12 is different from semiconductor device 100 shown in FIGS. 1 to 4 in that notch portion h has a pair of inclined surfaces 41s3. Specifically, notch portion h has the pair of inclined surfaces 41s3, an inner wall surface 41s4 and a bottom surface 41s5. The pair of inclined surfaces 41s3, inner wall surface 41s4 and bottom surface 41s5 form notch portion h.

Each of inclined surfaces 41s3 is continuous to side surface 41s2 and inner wall surface 41s4. Bottom surface 41s5 is a surface of notch portion h that is most recessed from the tip end of signal terminal 41 in the x direction. Bottom surface 41s5 is continuous to inner wall surface 41s4.

A portion of inclined surface 41s3 continuous to inner wall surface 41s4 is disposed between a portion of inclined surface 41s3 continuous to side surface 41s2 and bottom surface 41s5 in the x direction. Thus, each of the pair of inclined surfaces 41s3 is inclined toward a center A1 of signal terminal 41 in the width direction. From a different point of view, as shown in FIG. 12, in a plan view of main surface 11s, each of inclined surfaces 41s3 is inclined to face center A1. That is, a distance between the pair of inclined surfaces 41s3 becomes gradually shorter from the tip end of signal terminal 41 toward bottom surface 41s5. Thus, it becomes easier to insert metal wire 6 into notch portion h.

### <Functions and Effects>

According to semiconductor device 100 described above, notch portion h has inclined surface 41s3. Inclined surface 41s3 is inclined toward center A1.

With such a configuration, it becomes easier to insert metal wire 6 into notch portion h.

### Sixth Embodiment

### <Configuration of Semiconductor Device>

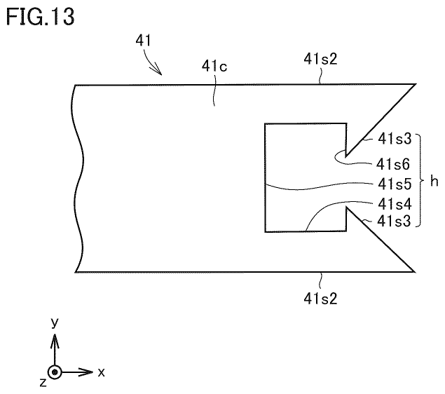

FIG. 13 is a plan view of signal terminal 41 according to a sixth embodiment. FIG. 13 corresponds to FIG. 12. Semiconductor device 100 shown in FIG. 13 basically has the same configuration as that of semiconductor device 100 shown in FIG. 12 and can achieve the same effect as that of semiconductor device 100 shown in FIG. 12. However, semiconductor device 100 shown in FIG. 13 is different from semiconductor device 100 shown in FIG. 12 in that notch portion h has a return surface 41s6. Specifically, return surface 41s6 protrudes from inner wall surface 41s4 toward center A1 (see FIG. 12). Return surface 41s6 is continuous to inner wall surface 41s4 and inclined surface 41s3. Return surface 41s6 faces bottom surface 41s5.

With such a configuration, push-out of metal wire 6 to the outside of notch portion h during manufacturing of semiconductor device 100 due to vibrations generated during transport of semiconductor device 100 or the injection pressure of the resin during injection of the resin is suppressed.

### <Functions and Effects>

According to semiconductor device 100 described above, notch portion h has return surface 41s6. Return surface 41s6 protrudes toward center A1 (see FIG. 12).

With such a configuration, push-out of metal wire 6 to the outside of notch portion h during manufacturing of semiconductor device 100 due to vibrations generated during transport of semiconductor device 100 or the injection pressure of the resin during injection of the resin is suppressed.

### Seventh Embodiment

A power conversion device to which the semiconductor device described in any one of the above-described first to sixth embodiments is applied will now be described. Although the present disclosure is not limited to a particular power conversion device, application of the present disclosure to a three-phase inverter will be described below as a seventh embodiment.

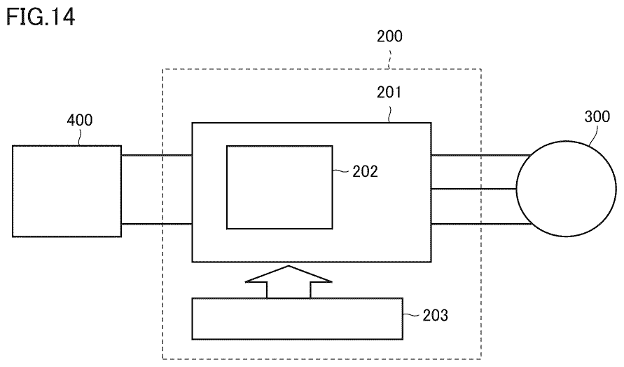

FIG. 14 is a block diagram showing a configuration of a power conversion system to which the power conversion device according to the present embodiment is applied. The power conversion system shown in FIG. 14 is constituted of a power supply 400, a power conversion device 200 and a load 300. Power supply 400 is a DC power supply and supplies DC power to power conversion device 200. Power supply 400 can be configured by a variety of types, and can be configured by a DC system, a solar battery or a storage battery, for example. Power supply 400 may be configured by a rectifier circuit or an AC/DC converter connected to an AC system. Alternatively, power supply 400 may be configured by a DC/DC converter that converts DC power output from the DC system into prescribed power.

Power conversion device 200 is a three-phase inverter connected between power supply 400 and load 300, and converts DC power supplied from power supply 400 into AC power and supplies the AC power to load 300. As shown in FIG. 14, power conversion device 200 includes a main conversion circuit 201 that converts DC power into AC power and outputs the AC power, and a control circuit 203 that outputs, to main conversion circuit 201, a control signal for controlling main conversion circuit 201.

Load 300 is a three-phase electric motor driven by the AC power supplied from power conversion device 200. Load 300 is not limited to a specific application, and load 300 is an electric motor mounted on various types of electric devices and is used as an electric motor for a hybrid vehicle, an electric vehicle, a railroad vehicle, an elevator, or an air-conditioning device, for example.

Details of power conversion device 200 will be described below. Main conversion circuit 201 includes a switching element and a freewheeling diode (not shown). When the switching element is switched, DC power supplied from power supply 400 is converted into AC power, which is supplied to load 300. While there are various types of specific circuit configurations for main conversion circuit 201, main conversion circuit 201 according to the present embodiment is a two-level three-phase full-bridge circuit and can be formed of six switching elements and six freewheeling diodes that are in antiparallel with the switching elements, respectively.

Semiconductor device 100 according to at least any one of the above-described first to sixth embodiments is applied as a semiconductor module 202 to at least any one of the switching elements and the freewheeling diodes of main conversion circuit 201. The six switching elements have every two switching elements connected in series to form upper and lower arms, and the upper and lower arms configure the full bridge circuit's phases (a U phase, a V phase and a W phase). Output terminals of the upper and lower arms, i.e., three output terminals of main conversion circuit 201 are connected to load 300.

Main conversion circuit 201 includes a drive circuit (not shown) that drives each switching element, and main conversion circuit 201 may have the drive circuit built into semiconductor module 202, or may include the drive circuit separately from semiconductor module 202. The drive circuit generates a drive signal for driving the switching elements of main conversion circuit 201, and supplies the drive signal to a control electrode of each switching element of main conversion circuit 201. Specifically, in accordance with the control signal from below-described control circuit 203, a drive signal for bringing a switching element into an on state and a drive signal for bringing a switching element into an off state are output to the control electrode of each switching element. When the switching element is maintained in the on state, the drive signal is a voltage signal (ON signal) equal to or higher than a threshold voltage of the switching element. When the switching element is maintained in the off state, the drive signal is a voltage signal (OFF signal) equal to or lower than the threshold voltage of the switching element.

Control circuit 203 controls the switching elements of main conversion circuit 201 such that desired power is supplied to load 300. Specifically, control circuit 203 calculates a time for which each switching element of main conversion circuit 201 should be turned on (ON time) based on the power to be supplied to load 300. For example, control circuit 203 can control main conversion circuit 201 by PWM control by which an ON time of a switching element is modulated in accordance with a voltage to be output. Control circuit 203 outputs a control command (control signal) to the drive circuit of main conversion circuit 201 such that the ON signal is output to a switching element to be turned on at each point in time and the OFF signal is output to a switching element to be turned off at each point in time. In response to this control signal, the drive circuit outputs the ON signal or the OFF signal as the drive signal to the control electrode of each switching element.

In the power conversion device according to the present embodiment, semiconductor device 100 according to any one of the above-described first to sixth embodiments is applied as semiconductor module 202 to at least any one of the switching elements and the freewheeling diodes of main conversion circuit 201. Therefore, the electrical insulating properties can be improved, and the reliability of the power conversion device can be improved.

Although the example in which the present disclosure is applied to a two-level three-phase inverter has been described in the present embodiment, the present disclosure is not limited thereto, and is applicable to various power conversion devices. Although a two-level power conversion device has been described in the present embodiment, a three-level power conversion device or a multi-level power conversion device may be adopted, and when electric power is supplied to a single-phase load, the present disclosure may be applied to a single-phase inverter. When electric power is supplied to a DC load or the like, the present disclosure is also applicable to a DC/DC converter or an AC/DC converter.

The power conversion device to which the present disclosure is applied is not limited to the above case where the load is an electric motor. For example, the power conversion device can also be used as a power supply device for an electric discharge machine, a laser beam machine, an induction heating cooking device, or a non-contact power feeding system, and furthermore can also be used as a power conditioner for a solar power generation system, a power storage system, or the like.

It should be noted that the semiconductor devices described in the embodiments can be variously combined as needed. Moreover, for the dependent claims in the scope of claims for patent, dependent forms corresponding to the combinations are also intended to be included.

Although the embodiments of the present disclosure have been described, it should be understood that the embodiments disclosed herein are illustrative and non-restrictive in every respect. The scope of the present disclosure is defined by the terms of the claims and is intended to include any modifications within the scope and meaning equivalent to the terms of the claims.

What is claimed is:

1. A semiconductor device comprising:
a substrate;
a semiconductor element disposed on the substrate;
a terminal disposed at a position farther than the semiconductor element when viewed from the substrate; and
a metal wire connecting the semiconductor element and the terminal, wherein
a notch portion is provided in the terminal, and
a part of the metal wire is inserted into the notch portion.

2. The semiconductor device according to claim 1, wherein
the semiconductor element has a main electrode and a signal electrode, and
the terminal has a main terminal connected to the main electrode with a joining portion interposed therebetween, and a signal terminal connected to the signal electrode via the metal wire.

3. The semiconductor device according to claim 1, wherein
the terminal includes a tip end region overlapping with the substrate in a plan view of the substrate, and an external region other than the tip end region, and
the metal wire is connected to the external region.

4. The semiconductor device according to claim 1, wherein
the notch portion is provided at a center of the terminal in a width direction.

5. The semiconductor device according to claim 4, wherein
the notch portion has an inclined surface inclined toward the center.

6. The semiconductor device according to claim 4, wherein
the notch portion has a return surface protruding toward the center.

7. The semiconductor device according to claim 1, wherein
the notch portion is provided at an end of the terminal in a width direction.

8. The semiconductor device according to claim 1, wherein
the metal wire has a vertex portion farthest from the semiconductor element, and a connection portion that is in contact with the terminal, and
the terminal has an inclined portion located between the connection portion and the vertex portion in a direction perpendicular to a main surface of the substrate.

9. A power conversion device comprising:
a main conversion circuit having the semiconductor device according to claim 1, to convert input power and output the converted input power; and
a control circuit to output a control signal for controlling the main conversion circuit to the main conversion circuit.
